(19) United States
(12) Patent Application Publication
(10) Pub. No.: US 2017/0152357 A1
(43) Pub. Date: Jun. 1, 2017

(54) ENCAPSULATING SHEET, PRODUCTION METHOD THEREOF, OPTICAL SEMICONDUCTOR DEVICE AND ENCAPSULATED OPTICAL SEMICONDUCTOR ELEMENT

(71) Applicant: NITTO DENKO CORPORATION, Ibaraki-shi, Osaka (JP)

(72) Inventors: Hirokazu MATSUDA, Osaka (JP); Ryota MITA, Osaka (JP); Hiroyuki KATAYAMA, Osaka (JP)

(73) Assignee: NITTO DENKO CORPORATION, Ibaraki-shi, Osaka (JP)

(21) Appl. No.: 15/319,895

(22) PCT Filed: Aug. 7, 2015
(86) PCT No.: PCT/JP2015/072482

§ 371 Date: Dec. 19, 2016

(30) Foreign Application Priority Data
Aug. 8, 2014 (JP) 2014-162267

(51) Int. Cl. C08J 5/18; H01L 33/56; C08K 3/00

(52) U.S. Cl. CPC C08J 5/18; C08K 3/0033; H01L 33/56; C08J 2383/07; H01L 2933/005

(57) ABSTRACT

An encapsulating sheet formed from an encapsulating composition including: a silicone resin composition containing alkenyl group-containing polysiloxane, a hydrosilyl group-containing polysiloxane, and a hydrosilylation catalyst; and an inorganic filler having a refraction of 1.50 or more and 1.60 or less and an average particle size of 10 μm or more and 50 μm or less. In the average composition formula (1) and the average composition formula (2), at least one of R² and R³ includes a phenyl group. A product produced by reaction of the silicone resin composition is represented by the average composition formula (3) below.

R⁵ₑSiO_{(4-e)/2} average composition formula (3):

The phenyl group content in R⁵ of the average composition formula (3) is 30 mol % or more and 55 mol % or less.

### TECHNICAL FIELD

The present invention relates to an encapsulating sheet, a production method thereof, an optical semiconductor device, and an encapsulated optical semiconductor element. In particular, the present invention relates to an encapsulating sheet, a production method thereof, an optical semiconductor device including an optical semiconductor element mounted on a substrate and encapsulated with the encapsulating sheet, and an encapsulated optical semiconductor element including an optical semiconductor element encapsulated with the encapsulating sheet.

### BACKGROUND ART

Conventionally, it has been known that an encapsulating material made of a silicone resin composition is used for encapsulating an optical semiconductor element. With the encapsulating material, an optical semiconductor element including terminals is embedded and is covered.

Patent Document 1 below recently has proposed, as an encapsulating material with excellent gas barrier properties against corrosive gas such as hydrogen sulfide gas or sulfuric acid gas, an encapsulating material for an optical semiconductor element containing a liquid phenol resin, and silicone resin containing a phenyl group in its molecule. The encapsulating material for an optical semiconductor element of Patent Document 1 is a liquid thermosetting resin composition, and is injected into a recess portion defined by a housing member surrounding the optical semiconductor element mounted on a substrate, and thereafter, cured by heat. The encapsulating material for an optical semiconductor element of Patent Document 1 after being cured suppresses penetration of corrosive gas, and prevents corrosion of the terminals of the optical semiconductor element.

### CITATION LIST

### Patent Document

### Patent Document 1: Japanese Unexamined Patent Publication No. 2011-178892

### SUMMARY OF THE INVENTION

### Problem to be Solved by the Invention

However, the liquid encapsulating material for an optical semiconductor element described in Patent Document 1 is disadvantageous in that it cannot be molded into a solid sheet having a desired thickness.

Blending a filler into the encapsulating material for an optical semiconductor element of Patent Document 1 to improve moldability of the sheet can be considered, but in such a case, disadvantages such as the following are caused: transparency of the sheet is reduced, or the filler sedimentation is caused in the liquid encapsulating material for an optical semiconductor element, causing non-homogenous dispersion of the filler.

An object of the present invention is to provide an encapsulating sheet that can be reliably and uniformly formed into a sheet with a desired thickness even if the phenyl group is contained, in which particles are dispersed homogenously, which has excellent transparency, and which can reliably encapsulate the optical semiconductor element; a production method thereof; an optical semiconductor device; and an encapsulated optical semiconductor element.

### Means for Solving the Problem

The present invention is as follows.

[1] An encapsulating sheet used to encapsulate an optical semiconductor element, the encapsulating sheet formed into a sheet from an encapsulating composition including:

a silicone resin composition containing an alkenyl group-containing polysiloxane having two or more alkenyl groups and/or cycloalkenyl groups in its molecule, a hydrosilyl group-containing polysiloxane having two or more hydrosilyl groups in its molecule, and a hydrosilylation catalyst, and

an inorganic filler having a refraction of 1.50 or more and 1.60 or less, and an average particle size of 10 μm or more and 50 μm or less,

wherein the alkenyl group-containing polysiloxane is represented by the average composition formula (1) below,

R¹ₐR²_{b}SiO_{(4-a-b)/2} average composition formula (1):

(where R¹ represents an alkenyl group having 2 to 10 carbon atoms and/or a cycloalkenyl group having 3 to 10 carbon atoms. R² represents an unsubstituted or substituted monovalent hydrocarbon group (excluding alkenyl group and cycloalkenyl group) having 1 to 10 carbon atoms. a is 0.05 or more and 0.50 or less, and b is 0.80 or more and 1.80 or less.)

the hydrosilyl group-containing polysiloxane is represented by the average composition formula (2) below,

H_{c}R³_{d}SiO_{(4-c-d)/2} average composition formula (2):

(where R³ represents an unsubstituted or substituted monovalent hydrocarbon group having 1 to 10 carbon atoms (excluding alkenyl group and/or cycloalkenyl group). c is 0.30 or more and 1.0 or less, and d is 0.90 or more and 2.0 or less.)

in the average composition formula (1) and the average composition formula (2), at least one of R² and R³ includes a phenyl group,

a product produced by reaction of the silicone resin composition is represented by the average composition formula (3) below,

R⁵ₑSiO_{(4-e)/2} average composition formula (3):

(where R⁵ represents an unsubstituted or substituted monovalent hydrocarbon group having 1 to 10 carbon atoms including a phenyl group (excluding alkenyl group and cycloalkenyl group). e is 1.0 or more and 3.0 or less), and

the phenyl group content in R⁵ of the average composition formula (3) is 30 mol % or more and 55 mol % or less.

[2] The encapsulating sheet of above-described [1], wherein the mixing ratio of the inorganic filler is 30 mass % or more and 80 mass % or less relative to the encapsulating composition.
[3] The encapsulating sheet of the above-described [1] or [2], wherein the silicone resin composition has two-stage curable properties, and is in B-stage.
[4] The encapsulating sheet of the above-described [3], wherein the silicone resin composition in B-stage has thermoplastic and thermosetting properties together.
[5] The encapsulating sheet of the any one of the above-described [1] to [4], wherein the shear storage modulus G′ at 80° C. obtained by dynamic viscoelasticity measurement under conditions of a frequency of 1 Hz, a temperature increase rate of 20° C./min, and a temperature range of 20 to 150° C. is 3 Pa or more and 140 Pa or less.
[6] The encapsulating sheet of any one of the above-described [1] to [5], wherein the transmittance of light having a wavelength of 460 nm is 70% or more when the thickness is 600 μm.
[7] A method for producing the encapsulating sheet of any one of the above-described [1] to [6], the method including forming a coating by applying the encapsulating composition, and heating the coating at 70° C. or more and 120° C. or less and for 8 minutes or more and 15 minutes or less.
[8] An optical semiconductor device including a substrate, an optical semiconductor element mounted on the substrate, and the encapsulating sheet of any one of the above-described [1] to [7] encapsulating the optical semiconductor element.
[9] An encapsulated optical semiconductor element including an optical semiconductor element, and the encapsulating sheet of the above-described [1] to [7] encapsulating the optical semiconductor element.

### Effects of the Invention

In the encapsulating sheet of the present invention, the inorganic filler has an average particle size in the above-described specific range, and therefore the encapsulating sheet is formed into a sheet having a desired thickness, and the inorganic filler is dispersed homogenously.

In the encapsulating sheet of the present invention, the inorganic filler has a refraction in the above-described range, and therefore difference between the refraction of the inorganic filler and the refraction of the silicone resin composition having the above-described phenyl group concentration can be reduced, and therefore, the encapsulating sheet is excellently transparent.

In the encapsulating sheet of the present invention, the product produced by reaction of the silicone resin composition has the phenyl group content in R⁵ of the average composition formula (3) in a specific range, and therefore the optical semiconductor element can be reliably embedded and encapsulated.

Therefore, the encapsulating sheet of the present invention has excellent moldability, transparency, and encapsulation characteristics.

The method for producing an encapsulating sheet of the present invention allows for production of an encapsulating sheet in which the inorganic filler is homogenously dispersed in the silicone resin composition, and which has a desired uniform thickness.

In the optical semiconductor device and encapsulated optical semiconductor element of the present invention, the optical semiconductor element is encapsulated with the encapsulating sheet with excellent moldability, transparency, and encapsulation characteristics, and therefore have excellent reliability and luminosity.

### BRIEF DESCRIPTION OF THE DRAWINGS

FIG. 1A to FIG. 1C show steps for producing the optical semiconductor device of the present invention in an embodiment using an embodiment of the encapsulating sheet of the present invention, FIG. 1A illustrating a preparation step, FIG. 1B illustrating an encapsulation step, and FIG. 1C illustrating a release step.

FIG. 2A to FIG. 2D show steps for producing an optical semiconductor device in a modified example using the encapsulating sheet of FIG. 1A, FIG. 2A illustrating a preparation step, FIG. 2B illustrating an encapsulation step and a first release step, FIG. 2C illustrating a second release step, and FIG. 2D illustrating a mounting step.

### DESCRIPTION OF EMBODIMENTS

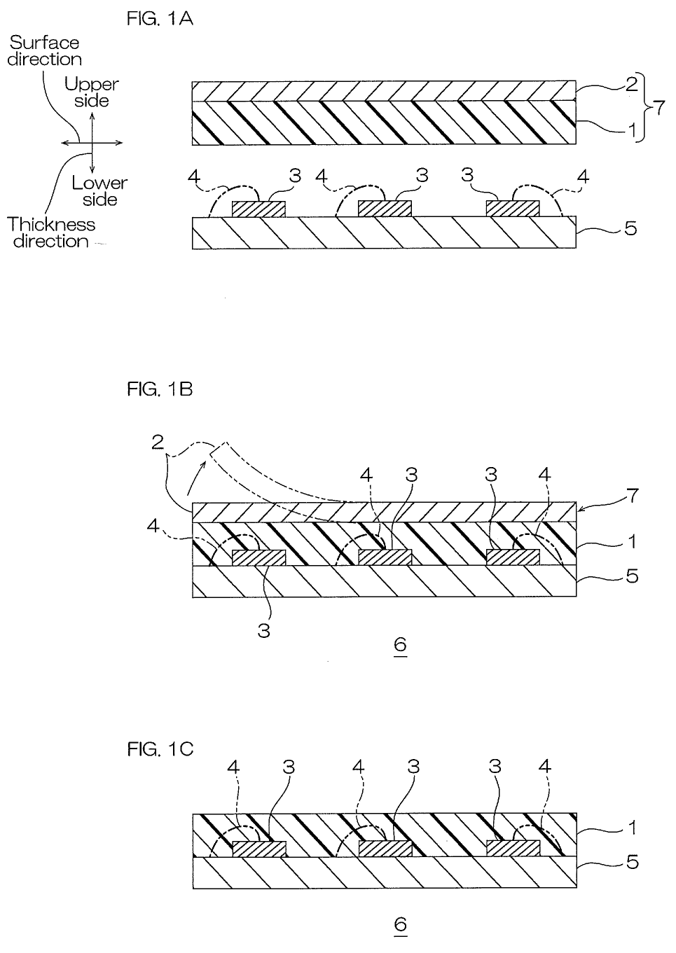

In FIG. 1A to FIG. 1C, the upper side on the plane of the sheet is referred to as upper side (one side in the first direction, one side in the thickness direction), the lower side on the plane of the paper is referred to as lower side (the other side in the first direction, the other side in the thickness direction).

### [Encapsulating Sheet 1]

An encapsulating sheet 1 in one embodiment of the present invention has, as shown in FIG. 1A, a flat plate shape. To be specific, the encapsulating sheet 1 has a predetermined thickness, extends in a predetermined direction perpendicular to the thickness direction of the encapsulating sheet 1, and has a flat upper face and a flat lower face. The encapsulating sheet 1 is not the optical semiconductor device 6 (ref: FIG. 1C) described later, but is a component of the optical semiconductor device 6. That is, the encapsulating sheet 1 is a component for producing the optical semiconductor device 6, does not include an optical semiconductor element 3 and a substrate 5 on which the optical semiconductor element 3 is mounted. As shown in FIG. 1A, the encapsulating sheet 1 is included in the encapsulating member 7 along with the release sheet 2.

The encapsulating member 7 includes a release sheet 2, and an encapsulating sheet 1 disposed on the surface (lower face) of the release sheet 2. Preferably, the encapsulating member 7 consists of a release sheet 2 and the encapsulating sheet 1. The encapsulating member 7 is distributed singularly as a component, and is an industrially applicable device.

The encapsulating sheet 1 is formed into a sheet from an encapsulating composition, and is used to encapsulate an optical semiconductor element 3 (ref: FIG. 1C).

### (Encapsulating Composition)

The encapsulating composition contains a silicone resin composition and an inorganic filler.

### (Silicone Resin Composition)

The silicone resin composition has, for example, two-stage curable properties. To be specific, the silicone resin composition has two-stage heat curable (thermosetting) properties or two-stage ultraviolet ray curable properties, and preferably has two-stage heat curable properties.

### (Silicone Resin Composition Material)

The silicone resin composition contains, for example, an alkenyl group-containing polysiloxane, a hydrosilyl group-containing polysiloxane, and a hydrosilylation catalyst.

The above-described components are described next.

### <Alkenyl Group-Containing Polysiloxane>

The alkenyl group-containing polysiloxane contains two or more alkenyl groups and/or cycloalkenyl groups in its molecule. The alkenyl group-containing polysiloxane is represented, to be specific, by the average composition formula (1) below.

R¹ₐR²_{b}SiO_{(4-a-b)/2} average composition formula (1):

(where R¹ represents an alkenyl group having 2 to 10 carbon atoms and/or a cycloalkenyl group having 3 to 10 carbon atoms. R² represents an unsubstituted or substituted monovalent hydrocarbon group (excluding alkenyl group and cycloalkenyl group) having 1 to 10 carbon atoms. a is 0.05 or more and 0.50 or less, and b is 0.80 or more and 1.80 or less.)
In formula (1), examples of the alkenyl group represented by R¹ include an alkenyl group having 2 to 10 carbon atoms such as a vinyl group, allyl group, propenyl group, butenyl group, pentenyl group, hexenyl group, heptenyl group, and octenyl group. Examples of the cycloalkenyl group represented by R¹ include a cycloalkenyl group having 3 to 10 carbon atoms such as a cyclohexenyl group and a norbornenyl group.

For R¹, preferably, an alkenyl group, more preferably, an alkenyl group having 2 to 4 carbon atoms, even more preferably, a vinyl group is used.

The alkenyl group represented by R¹ can be the same type or a plurality of different types.

The monovalent hydrocarbon group represented by R² is an unsubstituted or substituted monovalent hydrocarbon group having 1 to 10 carbon atoms other than the alkenyl group or cycloalkenyl group.

Examples of the unsubstituted monovalent hydrocarbon group include an alkyl group having 1 to 10 carbon atoms such as a methyl group, ethyl group, propyl group, isopropyl group, butyl group, isobutyl group, sec-butyl group, tert-butyl group, pentyl group, hexyl group, pentyl group, heptyl group, octyl group, 2-ethylhexyl group, nonyl group, and decyl group; a cycloalkyl group having 3 to 6 carbon atoms such as a cyclopropyl, cyclobutyl group, cyclopentyl group, and cyclohexyl group; an aryl group having 6 to 10 carbon atoms such as a phenyl group, tolyl group, and naphthyl group; and an aralkyl group having 7 to 8 carbon atoms such as a benzyl group and benzylethyl group. Preferably, an alkyl group having 1 to 3 carbon atoms, an aryl group having 6 to 10 carbon atoms, more preferably, methyl and phenyl are used.

Meanwhile, examples of the substituted monovalent hydrocarbon group include those unsubstituted monovalent hydrocarbon groups described above in which the hydrogen atom therein is substituted with a substituent.

Examples of the substituent include halogen atoms such as chlorine atoms, and glycidyl ether groups.

For the substituted monovalent hydrocarbon group, to be specific, a 3-chloropropyl group and a glycidoxypropyl group are used.

The monovalent hydrocarbon group can be any of unsubstituted and substituted, preferably, the monovalent hydrocarbon group is unsubstituted.

The monovalent hydrocarbon group represented by R² can be the same type or a plurality of different types. Preferably, methyl and phenyl are used in combination.

a is preferably 0.10 or more and 0.40 or less.
b is preferably 1.5 or more and 1.75 or less.

The alkenyl group-containing polysiloxane has a weight-average molecular weight of, for example, 100 or more, preferably 500 or more, and for example, 10000 or less, preferably 5000 or less. The weight-average molecular weight of the alkenyl group-containing polysiloxane is measured by gel permeation chromatography based on polystyrene standard.

The alkenyl group-containing polysiloxane is prepared by a suitable method, or those commercially available products can be used.

The alkenyl group-containing polysiloxane can be the same type or a plurality of different types.

### <Hydrosilyl Group-Containing Polysiloxane>

The hydrosilyl group-containing polysiloxane contains, for example, two or more hydrosilyl groups (SiH group) in its molecule. The hydrosilyl group-containing polysiloxane is, to be specific, represented by the average composition formula (2) below.

H_{c}R³_{d}SiO_{(4-c-d)/2} average composition formula (2):

(where R³ represents an unsubstituted or substituted monovalent hydrocarbon group having 1 to 10 carbon atoms (excluding alkenyl group and/or cycloalkenyl group). c is 0.30 or more and 1.0 or less, and d is 0.90 or more and 2.0 or less.)
Examples of the unsubstituted or substituted monovalent hydrocarbon group having 1 to 10 carbon atoms represented by R³ in formula (2) include the unsubstituted or substituted monovalent hydrocarbon group having 1 to 10 carbon atoms represented by R² in formula (1). Preferably, the unsubstituted monovalent hydrocarbon group having 1 to 10 carbon atoms, more preferably, the alkyl group having 1 to 10 carbon atoms and the aryl group having 6 to 10 carbon atoms are used, even more preferably, a phenyl group and a methyl group are used in combination.
c is preferably 0.5 or less.
d is preferably 1.3 or more and 1.7 or less.

The hydrosilyl group-containing polysiloxane has a weight-average molecular weight of, for example, 100 or more and preferably 500 or more, and for example, 10000 or less, preferably 5000 or less. The weight-average molecular weight of the hydrosilyl group-containing polysiloxane is measured by gel permeation chromatography based on polystyrene standard.

The hydrosilyl group-containing polysiloxane is prepared by a suitable method, or those commercially available products can be used.

In the above-described average composition formula (1) and the average composition formula (2), at least one of hydrocarbon group in R² and R³ includes a phenyl group. Preferably, both hydrocarbons in R² and R³ include the phenyl groups.

At least one of R² and R³ includes the phenyl group, and therefore the silicone resin composition containing the above-described alkenyl group-containing polysiloxane represented by the average composition formula (1) and/or the hydrosilyl group-containing polysiloxane represented by the average composition formula (2) is prepared as a phenyl silicone resin composition containing a phenyl group.

The hydrosilyl group-containing polysiloxane can be the same type or a plurality of different types.

The hydrosilyl group-containing polysiloxane is blended so that the ratio of the mole number of alkenyl group and cycloalkenyl group of the alkenyl group-containing polysiloxane relative to the mole number of hydrosilyl group of the hydrosilyl group-containing polysiloxane (mole number of alkenyl group and cycloalkenyl group/mole number of hydrosilyl group) is, for example, 1/30 or more, preferably 1/3 or more and for example, 30/1 or less, preferably 3/1 or less.

### <Hydrosilylation Catalyst>

The hydrosilylation catalyst is not particularly limited as long as it is a substance (addition catalyst) that improves the reaction velocity/rate of hydrosilylation reaction (hydrosilyl addition) of the alkenyl group and/or cycloalkenyl group of the alkenyl group-containing polysiloxane with the hydrosilyl group of the hydrosilyl group-containing polysiloxane, and examples thereof include metal catalysts. Examples of the metal catalyst include platinum catalysts such as platinum black, platinum chloride, chloroplatinic acid, a platinum-olefin complex, a platinum-carbonyl complex, and platinum-acetylacetate; palladium catalysts; and rhodium catalysts.

The hydrosilylation catalyst is blended, in an amount of metal of the metal catalyst (to be specific, metal atom), relative to the alkenyl group-containing polysiloxane and the hydrosilyl group-containing polysiloxane, based on mass, for example, 1.0 ppm or more, and for example, 10000 ppm or less, preferably 1000 ppm or less, more preferably 500 ppm or less.

### (Preparation of Silicone Resin Composition)

The silicone resin composition is prepared, by blending the alkenyl group-containing polysiloxane, hydrosilyl group-containing polysiloxane, and hydrosilylation catalyst in the above-described ratio.

To be specific, the silicone resin composition is prepared as a two-stage curable (preferably, two-stage heat curable) resin composition in A stage (liquid state) by blending the alkenyl group-containing polysiloxane, hydrosilyl group-containing polysiloxane, and hydrosilylation catalyst.

The A-stage silicone resin composition can be brought into C-stage (completely cured solid) going through A-stage (liquid state) and then to B-stage (semi-cured solid or semi-solid).

To be more specific, in the A-stage silicone resin composition, the alkenyl group and/or cycloalkenyl group of the alkenyl group-containing polysiloxane and the hydrosilyl group of the hydrosilyl group-containing polysiloxane undergo hydrosilylation reaction under conditions described later to produce the B-stage silicone resin composition.

The silicone resin composition has a refraction of, for example, 1.50 or more, and for example, 1.60 or less. The refraction of the silicone resin composition is calculated by an Abbe refractometer. The refraction of the silicone resin composition is calculated, when the silicone resin composition has two-stage curable properties, as the refraction of the C-stage silicone resin composition (corresponding to the product described later).

The silicone resin composition is blended, relative to the encapsulating composition, for example, 20 mass % or more and preferably 25 mass % or more, and for example, 70 mass % or less, preferably 50 mass % or less, more preferably less than 50 mass %, even more preferably 40 mass % or less, and particularly preferably 30 mass % or less. When the silicone resin composition is blended in the above-described range, moldability of the encapsulating sheet 1 can be ensured.

### (Inorganic Filler)

The inorganic filler is blended in the encapsulating composition to improve moldability of the encapsulating sheet 1 (ref: FIG. 1A). To be specific, the inorganic filler is blended in the silicone resin composition before reaction (to be specific, A-stage). Examples of the inorganic filler include inorganic particles (inorganic substance) including oxides such as silica (SiO₂), talc (Mg₃(Si₄O₁₀)(HO)₂), alumina (Al₂O₃), boron oxide (B₂O₃), calcium oxide (CaO), zinc oxide (ZnO), strontium oxide (SrO), magnesium oxide (MgO), zirconium oxide (ZrO₂), barium oxide (BaO), and antimony oxide (Sb₂O₃); and nitrides such as aluminum nitride (AlN) and silicon nitride (Si₃N₄). Examples of the inorganic filler also include a composite inorganic particles prepared from the above-described examples of the inorganic substance, and preferably, composite inorganic oxide particles (to be specific, glass particles, etc.) prepared from oxide are used.

The composite inorganic oxide particles contain, for example, silica, or silica and boron oxide as main components, and alumina, calcium oxide, zinc oxide, strontium oxide, magnesium oxide, zirconium oxide, barium oxide, and antimony oxide as sub components. The composite inorganic oxide particles have a main component content relative to the composite inorganic oxide particles of, for example, more than 40 mass %, preferably 50 mass % or more, and for example, 90 mass % or less, preferably 80 mass % or less. The sub component content is the remaining portion of the above-described main component content.

The composite oxide particles are produced as follows: the above-described main component and the sub component are blended; the mixture is heated to be melted, and the melt is quenched; thereafter, the product is ground by, for example, a ball mill; thereafter, as necessary, suitable surface treatment (to be specific, formed into sphere, etc.) is given.

The shape of the inorganic filler is not particularly limited, and for example, the shape can be spherical, platy, and acicular. Preferably, in view of flowability, the shape can be spherical. The inorganic filler has an average particle size of, 10 μm or more, preferably 15 μm or more, and 50 μm or less, preferably 40 μm or less, more preferably 30 μm or less, even more preferably 25 μm or less. When the average particle size of the inorganic filler is more than the above-described upper limit, the inorganic filler tends to be sedimented in the encapsulating composition (varnish described later). Meanwhile, when the inorganic filler has an average particle size of below the above-described lower limit, sheet moldability of the encapsulating composition tends to be reduced, or transparency of the encapsulating sheet 1 (ref: FIG. 1A) tends to be reduced. The average particle size of the inorganic filler is calculated as D50 value. To be specific, the average particle size of the inorganic filler is calculated by a laser diffraction particle size distribution analyzer.

The inorganic filler has a refraction of 1.50 or more, preferably 1.52 or more, and 1.60 or less, preferably 1.58 or less. When the inorganic filler has a refraction within the above-described range, the difference between the above-described refraction of the silicone resin composition and the refraction of the inorganic filler can be set within a desired range. That is, the absolute value of the difference in refraction between the silicone resin composition and the inorganic filler can be made smaller, and therefore, transparency of the encapsulating sheet 1 can be improved. The refraction of the inorganic filler is calculated by an Abbe refractometer.

The absolute value of the difference in refraction between the silicone resin composition and the inorganic filler is, for example, 0.10 or less, preferably 0.05 or less, and usually, for example, 0 or more. When the difference in the absolute value of the above-described refraction is the above-described upper limit or less, transparency of the encapsulating sheet 1 will be excellent.

The inorganic filler is blended relative to the encapsulating composition in an amount of, for example, 30 mass % or more, preferably 50 mass % or more, more preferably more than 50 mass %, even more preferably 60 mass % or more, particularly preferably 70 mass % or more, and for example, 80 mass % or less, preferably 75 mass % or less. The inorganic filler is blended relative to 100 parts by mass of the silicone resin composition in an amount of, for example, 50 parts by mass or more, preferably 100 parts by mass or more, more preferably 200 parts by mass or more, and for example, 400 parts by mass or less, preferably 300 parts by mass or less.

When the inorganic filler is blended in the above-described range, the inorganic filler ensures excellent moldability of the encapsulating sheet 1.

### [Production of Encapsulating Sheet]

To produce the encapsulating sheet 1, first, the above-described encapsulation composition containing the silicone resin composition and the inorganic filler is prepared. To be specific, when the silicone resin composition has two-stage curable properties, the encapsulation composition containing the A-stage silicone resin composition and the inorganic filler is prepared.

For example, the silicone resin composition and the inorganic filler are blended with the above-described mixing ratio. Furthermore, additives such as phosphor can be added to these components at a suitable ratio.

In this manner, the encapsulating composition in which the inorganic filler is dispersed in the silicone resin composition is prepared as varnish.

The varnish has a viscosity at 25° C. of, for example, 1,000 mPa·s or more, preferably 4,000 mPa·s or more, and for example, 1,000,000 mPa·s or less, preferably 200,000 mPa·s or less. The viscosity is measured by adjusting the temperature of the varnish to 25° C., and using an E-type cone.

Then, the prepared varnish is applied. To be specific, as shown in FIG. 1A, the varnish is applied on the surface (lower surface) of the release sheet 2.

The release sheet 2 is removably attached to the back surface (upper face in FIG. 1A) of the encapsulating sheet 1 to protect the encapsulating sheet 1 until the optical semiconductor element 3 is encapsulated with the encapsulating sheet 1. That is, the release sheet 2 is a flexible film that is laminated on the back surface of the encapsulating sheet 1 while the encapsulating member 7 is shipped, transported, and stored to cover the back surface of the encapsulating sheet 1, and can be released from the back surface of the encapsulating sheet 1 so as to be bent substantially in letter U-shape right before use of the encapsulating member 7. That is, the release sheet 2 does not include the encapsulating sheet 1 and/or the optical semiconductor element 3 encapsulated with the encapsulating sheet 1. That is, the release sheet 2 consists only of the flexible film. The surface of the release sheet 2 to be attached, that is, the face contacting the encapsulating sheet 1 is treated, as necessary, with fluorine for releasing.

Examples of the release sheet 2 include polymer films such as polyethylene films and polyester films (PET, etc.); ceramic sheets; and metal foil. Preferably, polymer films are used. The shape of the release sheet 2 is not particularly limited, and for example, the shape is a generally rectangular shape (including strips, elongated shape) when viewed from the top. The release sheet 2 has a thickness of, for example, 1 μm or more, preferably 10 μm or more, and for example, 2,000 μm or less, preferably 1,000 μm or less.

To apply the varnish on the surface of the release sheet 2, for example, applicator devices such as a dispenser, applicator, and slit die coater are used.

The application of the varnish onto the release sheet 2 forms a coating.

Thereafter, the coating is semi-cured. To be specific, when the silicone resin composition is two-stage heat curable, the coating is heated. The heating conditions are as follows: the heating temperature is 70° C. or more, preferably 80° C. or more, and 120° C. or less, preferably 100° C. or less. When the heating temperature is within the above-described range, the silicone resin composition can be reliably brought into B-stage. The heating time is, for example, 5 minutes or more, preferably 8 minutes or more, and for example, 30 minutes or less, preferably 20 minutes or less.

When the silicone resin composition has two-stage ultraviolet ray curable properties, the coating is applied with ultraviolet ray. To be specific, the coating is applied with ultraviolet ray using, for example, a UV lamp.

In this manner, the A-stage silicone resin composition in the coating is brought into B-stage.

That is, in the silicone resin composition, hydrosilylation reaction between the alkenyl group and/or cycloalkenyl group and the hydrosilyl group progresses halfway, and ceases once.

When the silicone resin composition is brought into B-stage, the encapsulating sheet 1 (or coating) is repelled from the release sheet 2, and therefore, the encapsulating sheet 1 goes through coagulation when viewed from the top, and the area viewed from the top is reduced. As a result, the encapsulating sheet 1 tends to have an increased thickness. Meanwhile, when the encapsulating sheet 1 is brought into B-stage by heating, the encapsulating sheet 1 tends to shrink with heating, in particular, the encapsulating sheet 1 tends to be thinner in the thickness direction. Therefore, the increase in the thickness of the encapsulating sheet 1 by being repelled from the release sheet 2 and the decrease in thickness from the shrinkage from heating offset each other, and the thickness of the encapsulating sheet 1 substantially does not change.

In this manner, as shown in FIG. 1A, the encapsulating member 7 including the release sheet 2 and the encapsulating sheet 1 laminated on the release sheet 2 is obtained.

In the encapsulating sheet 1, the inorganic filler is dispersed homogenously in the silicone resin composition as matrix. When the silicone resin composition is in semi-cured (B-stage) state, the encapsulating sheet 1 is also in semi-cured (B-stage) state, as described above.

The encapsulating sheet 1 in semi-cured (B-stage) state has flexibility, and is in a state that can be brought into completely cured (C-stage) state (that is, can produce a C-stage product) described later after being in semi-cured (B-stage) state.

The encapsulating sheet 1 in B-stage has plasticity and also is curable. To be specific, the encapsulating sheet 1 in B-stage has both thermoplastic and thermosetting properties. That is, the encapsulating sheet 1 in B-stage can be plasticized once by heating, and then can be cured.

The thermoplastic temperature of the encapsulating sheet 1 is, for example, 40° C. or more, preferably 60° C. or more, and for example, 120° C. or less, preferably 100° C. or less. The thermoplastic temperature is a temperature at which the encapsulating sheet 1 shows thermoplasticity. To be specific, the thermoplastic temperature is a temperature at which the silicone resin composition in B-stage softens by heating, and substantially the same as the softening temperature.

The encapsulating sheet 1 has a heat curing temperature (thermosetting temperature) of, for example, 100° C. or more, preferably 120° C. or more, and for example, 150° C. or less. The heat curing temperature is a temperature at which the encapsulating sheet 1 in B-stage shows thermosetting properties, to be specific, a temperature at which the plasticized encapsulating sheet 1 is completely cured by heat and solidified.

### (Physical Properties of Encapsulating Sheet)

The encapsulating sheet 1 (when the silicone resin composition has two-stage curable properties, encapsulating sheet 1 containing B-stage silicone resin composition, that is, encapsulating sheet 1 in B-stage) has a shear storage modulus G′ at 80° C. of, for example, 3 Pa or more, preferably 12 Pa or more, and for example, 140 Pa or less, preferably 70 Pa or less. The encapsulating sheet 1 with a shear storage modulus G′ of 80° C. of the above-described upper limit or less allows for effective prevention of damages on the optical semiconductor element 3 and the wire 4 at the time of encapsulating the optical semiconductor element 3 to be described next. Meanwhile, when the encapsulating sheet 1 has a shear storage modulus G′ at 80° C. of the above-described lower limit or more, excellent shape retainability of the encapsulating sheet 1 at the time of encapsulating the optical semiconductor element 3 can be ensured, and handleability of the encapsulating sheet 1 can be improved. When the encapsulating sheet 1 has a shear storage modulus G′ at 80° C. of the above-described lower limit or more, uniformity of the thickness of the encapsulating sheet 1 can be ensured, and the thickness can be adjusted to a desired thickness.

The shear storage modulus G′ at 80° C. of the encapsulating sheet 1 is obtained by dynamic viscoelasticity measurement under conditions of a frequency of 1 Hz, a temperature increase rate of 20° C./min, and a temperature range of 20 to 150° C.

When the thickness is 600 μm, the encapsulating sheet 1 has a transmittance to light having a wavelength of 460 nm of, for example, 70% or more, preferably 80% or more, more preferably 90% or more, even more preferably 95% or more, and for example, 100% or less. When the transmittance is the above-described lower limit or more, after the optical semiconductor element 3 is encapsulated, light emitted from the optical semiconductor element 3 can be sufficiently transmitted. The transmittance of the encapsulating sheet 1 is measured, for example, by using an integrating sphere.

### [Production of Optical Semiconductor Device]

Next, a method for producing an optical semiconductor device 6 in which an optical semiconductor element 3 is encapsulated using an encapsulating sheet 1 is described with reference to FIG. 1A to FIG. 1C.

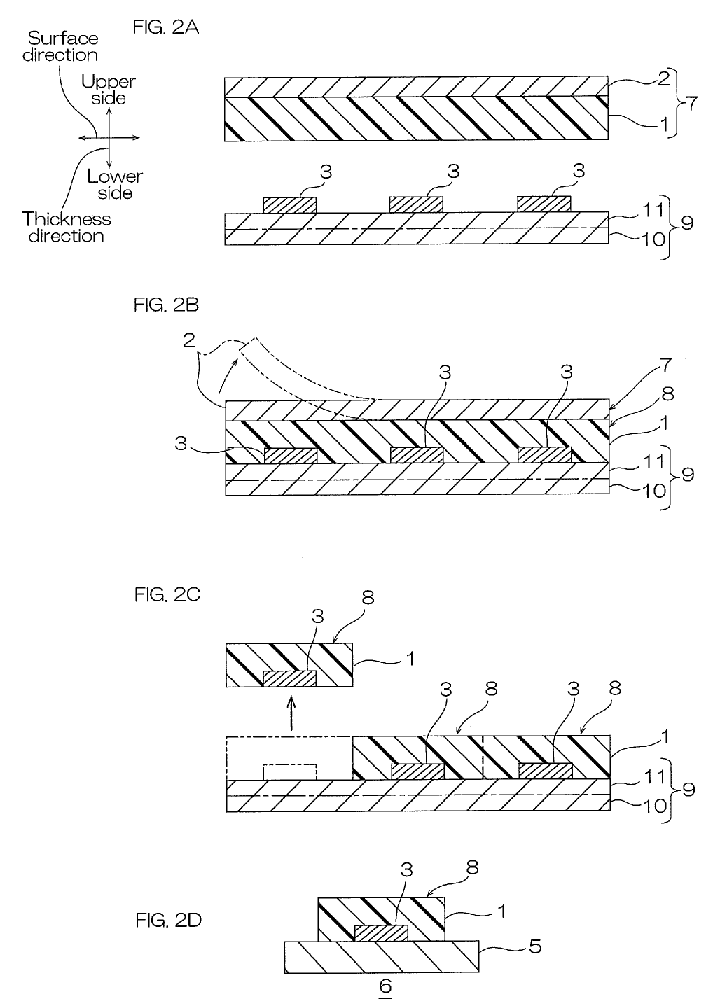

The method for producing an optical semiconductor device 6 includes, for example, a preparation step (ref: FIG. 1A), an encapsulation step (ref: FIG. 2B), and a release step (ref: FIG. 1C). The steps are described in the following.

### (Preparation Step)

In the preparation step, as shown in FIG. 1A, an encapsulating sheet 1 laminated on a release sheet 2, substrate 5, and optical semiconductor elements 3 mounted on the substrate 5 are prepared.

The encapsulating sheet 1 is prepared, when the silicone resin composition has two-stage curable properties, as a silicone resin composition in B-stage.

The substrate 5 is made, for example, of an insulating substrate. A conductive pattern (not shown) including an electrode is formed on the surface of the substrate 5.

A plurality of the optical semiconductor elements 3 are mounted on the substrate 5, and the plurality of optical semiconductor elements 3 are arranged in line in spaced-apart relation along the surface direction (direction perpendicular to the thickness direction). The optical semiconductor elements 3 are connected to the electrode (not shown) of the substrate 5 by wire bonding. In wire bonding connection, the terminal (not shown) provided on the upper face of the optical semiconductor element 3 is electrically connected to the electrode (not shown) provided on the upper face of the substrate 5 through wire 4 (ref: phantom line).

The optical semiconductor element 3 may be flip chip mounted (ref: solid line) on the substrate 5.

### (Encapsulation Step)

In the encapsulation step, after the preparation step, as shown in FIG. 1B, the optical semiconductor element 3 is encapsulated with encapsulating sheet 1 (when the silicone resin composition has two-stage curable properties, encapsulating sheet 1 in B-stage). To be specific, when the optical semiconductor elements 3 are connected to the substrate 5 by wire bonding, the optical semiconductor elements 3 and the wires 4 are embedded.

In particular, the encapsulating sheet 1 is disposed next to the optical semiconductor element 3 and the wire 4. To be specific, the encapsulating sheet 1 is placed on the upper face of the optical semiconductor element 3, and the encapsulating sheet 1 in B-stage is plasticized (softened). In this manner, the optical semiconductor element 3 and the wire 4 are embedded. To plasticize the encapsulating sheet 1, for example, when the silicone resin composition has two-stage heat curable properties, the encapsulating sheet 1 in B-stage is heated (first heating step).

The heating temperature is a temperature that is the same as the thermoplastic temperature of the encapsulating sheet 1 or more, and a temperature less than the heat curing temperature of the encapsulating sheet 1. To be specific, the heating temperature is, for example, 40° C. or more, preferably 60° C. or more, and for example, 120° C. or less, preferably 100° C. or less. The heating time is, for example, 5 minutes or more, preferably 8 minutes or more, and for example, 30 minutes or less, preferably 20 minutes or less.

To heat the encapsulating sheet 1 in B-stage, for example, the substrate 5 on which the optical semiconductor element 3 is mounted is placed on the surface of a hot plate (not shown) in advance to heat the substrate 5 and the optical semiconductor element 3 (also including wire 4), then, the encapsulating sheet 1 is placed on the upper face of the optical semiconductor element 3. Alternatively, the substrate 5 on which the optical semiconductor element 3 is mounted and/or the encapsulating sheet 1 laminated on the release sheet 2 can be put into a heating furnace.

In this manner, the encapsulating sheet 1 exhibits thermoplasticity as motility of alkenyl group-containing polysiloxane and/or hydrosilyl group-containing polysiloxane in the silicone resin composition in B-stage increases. Therefore, the encapsulating sheet 1 is plasticized, and then flows between the optical semiconductor elements 3 that are next to each other, and covers the wires 4 with no gaps. In this manner, the optical semiconductor element 3 and the wire 4 are embedded with the encapsulating sheet 1, thereby being encapsulated. That is, the encapsulating sheet 1 covers the upper face and the side face of the optical semiconductor element 3, and is filled between the optical semiconductor elements 3 that are disposed next to each other in the surface direction.

At this time, the release sheet 2 moves relatively to the substrate 5 and the optical semiconductor element 3 so as to be closer to each other without applying pressure.

Thereafter, the encapsulating sheet 1 in B-stage is cured. To be specific, the silicone resin composition in B-stage of the encapsulating sheet 1 is completely cured.

To be specific, when the silicone resin composition has two-stage heat curable properties, the encapsulating sheet 1 is heated. The heating temperature is the same as the heat curing temperature of the encapsulating sheet 1 or more, to be specific, for example, 100° C. or more, preferably 120° C. or more, and for example, 150° C. or less. The heating time is, for example, 10 minutes or more, preferably 30 minutes or more, and for example, 180 minutes or less, preferably 120 minutes or less.

In this manner, the silicone resin composition of the plasticized encapsulating sheet 1 is cured (brought into C-stage). In this manner, the silicone resin composition is completely reacted to obtain a product.

### (Product)

In the reaction of the silicone resin composition (reaction to be brought into C-stage), hydrosilyl addition reaction of the alkenyl group and/or cycloalkenyl group of the alkenyl group-containing polysiloxane and the hydrosilyl group of the hydrosilyl group-containing polysiloxane is further accelerated. Thereafter, alkenyl group and/or cycloalkenyl group, or hydrosilyl group of the hydrosilyl group-containing polysiloxane disappears, and hydrosilyl addition reaction is completed, thereby producing a silicone resin composition in C-stage, that is, a product (cured product). That is, by completion of the hydrosilyl addition reaction, in the silicone resin composition, curable characteristics (to be specific, thermosetting properties) are exhibited.

The silicone resin composition in C-stage still works as a matrix that disperses the inorganic filler. The silicone resin composition in C-stage is a cured product, and therefore the encapsulating sheet 1 is a cured substance containing a cured product of the silicone resin composition and the inorganic filler dispersed homogenously therein.

The above-described product is represented by the average composition formula (3) below.

R⁵ₑSiO_{(4-e)/2} average composition formula (3):

(where R⁵ represents an unsubstituted or substituted monovalent hydrocarbon group having 1 to 10 carbon atoms including a phenyl group (excluding alkenyl group and cycloalkenyl group). e is 1.0 or more and 3.0 or less.)
Examples of the unsubstituted or substituted monovalent hydrocarbon group having 1 to 10 carbon atoms represented by R⁵ include those given as examples for the unsubstituted or substituted monovalent hydrocarbon group having 1 to 10 carbon atoms represented by R² in formula (1) and unsubstituted or substituted monovalent hydrocarbon group having 1 to 10 carbon atoms represented by R³ in formula (2). Preferably, unsubstituted monovalent hydrocarbon group, more preferably alkyl group having 1 to 10 carbon atoms, aryl group having 6 to 10 carbon atoms, even more preferably, phenyl group and methyl group are used in combination.

The product has a phenyl group content in R⁵ of the average composition formula (3) of, 30 mol % or more, preferably 35 mol % or more, and 55 mol % or less, preferably 50 mol % or less.

When the product has the phenyl group content in R⁵ of the average composition formula (3) of below the above-described lower limit, thermoplasticity of the encapsulating sheet 1 in B-stage (ref: FIG. 1A) cannot be ensured, that is, the shear storage modulus G′ at 80° C. of the encapsulating sheet 1 described later is more than the desired range, and therefore the optical semiconductor element 6 cannot be embedded and encapsulated reliably.

Meanwhile, when the product has the phenyl group content in R⁵ of the average composition formula (3) of the above-described upper limit or less, reduction in flexibility of the encapsulating sheet 1 (ref: FIG. 1A) in C-stage can be prevented.

The phenyl group content of the product in R⁵ of the average composition formula (3) is a phenyl group concentration in the monovalent hydrocarbon group (represented by R⁵ in average composition formula (3)) directly connected to the silicon atom in the product.

The phenyl group content of the product in R⁵ of the average composition formula (3) is calculated with ¹H-NMR and ²⁹Si-NMR. The calculation method for the phenyl group content in R⁵ is described in detail in Examples described later, and for example, it is calculated with ¹H-NMR and ²⁹Si-NMR based on the description in WO2011/125463.

### (Release Step)

In the release step, after the encapsulation step, as shown in the phantom line in FIG. 1B and FIG. 1C, the release sheet 2 is released from the encapsulating sheet 1. To be specific, the release sheet 2 is stripped from the back surface of the encapsulating sheet 1 so as to be bent in substantially letter U-shape.

In this manner, an optical semiconductor device 6 including a substrate 5, an optical semiconductor element 3 mounted on the substrate 5, and an encapsulating sheet 1 encapsulating the optical semiconductor element 3 is produced.

### [Operations and Effects]

Then, in the encapsulating sheet 1, the inorganic filler has an average particle size in the above-described specific range, and therefore is molded into a sheet having a desired thickness, and the inorganic filler is dispersed homogenously.

In the encapsulating sheet 1, the inorganic filler has a refraction in the above-described range, and therefore the difference between the refraction of the inorganic filler and the refraction of the silicone resin composition having the above-described phenyl group concentration can be reduced, and therefore the encapsulating sheet 1 has excellent transparency.

Furthermore, in the encapsulating sheet 1, the product obtained by reaction of the silicone resin composition has a phenyl group content in R⁵ of the average composition formula (3) in a specific range, and therefore the optical semiconductor element 3 can be embedded and encapsulated reliably.

Therefore, the encapsulating sheet 1 has excellent moldability, transparency, and encapsulation characteristics.

With the method for producing the encapsulating sheet 1, the encapsulating sheet 1 in which the inorganic filler is homogenously dispersed in the silicone resin composition can be produced with a desired uniform thickness.

In the optical semiconductor device 6, the optical semiconductor element 3 is encapsulated with the encapsulating sheet 1 with excellent moldability, transparency, and encapsulation characteristics, and therefore has excellent reliability and luminosity.

### Modified Example

In Modified Example, for those members and steps that are the same as the above-described embodiment, the same reference numerals are given and detailed descriptions thereof are omitted.

In the above-described embodiment, as shown in FIG. 1B, the optical semiconductor element 3 mounted on the substrate 5 is encapsulated with the encapsulating sheet 1, but for example, as shown in FIG. 2B, the optical semiconductor element 3 supported by the support sheet 9 but not yet mounted on the substrate 5 can also be encapsulated.

In the Modified Example, the method for producing an optical semiconductor device 6 includes, for example, a preparation step (ref: FIG. 2A), an encapsulation step (ref: FIG. 2B), a first release step (ref: phantom line in FIG. 2B), a second release step (ref: FIG. 2C), and a mounting step. The steps are described in the following.

### (Preparation Step)

In the preparation step, as shown in FIG. 2A, an encapsulating sheet 1 laminated on a release sheet 2, a support sheet 9, and optical semiconductor elements 3 supported by the support sheet 9 are prepared.

The support sheet 9 includes a support plate 10, and a pressure-sensitive adhesive layer 11 laminated on the upper face of the support plate 10.

The support plate 10 is a plate shape extending in the surface direction, provided on a lower portion of the support sheet 9, and is formed into a shape that is substantially the same as that of the support sheet 9 when viewed from the top. The support plate 10 is made of a hard material that cannot be extended in the surface direction, and to be specific, examples of such a material include oxides such as silicon oxide (quartz, etc.) and alumina; metals such as stainless steel; and silicon. The support plate 10 has a thickness of, for example, 0.1 mm or more, preferably 0.3 mm or more, and for example, 5 mm or less, preferably 2 mm or less.

The pressure-sensitive adhesive layer 11 is formed on the entire upper face of the support plate 10. Examples of the adhesive material that fours the pressure-sensitive adhesive layer 11 include pressure-sensitive adhesives such as acrylic pressure-sensitive adhesives, and silicone-based pressure-sensitive adhesives. The pressure-sensitive adhesive layer 11 can also be formed, for example, from an active energy ray application release sheet (to be specific, active energy ray application release sheet described in Japanese Unexamined Patent Publication No. 2005-286003) that reduces adhesion by application of active energy ray. The pressure-sensitive adhesive layer 11 has a thickness of, for example, 0.1 mm or more, preferably 0.2 mm or more, and 1 mm or less, preferably 0.5 mm or less.

To prepare the support sheet 9, for example, the support plate 10 and the pressure-sensitive adhesive layer 11 are bonded. The pressure-sensitive adhesive layer 11 can be directly laminated on the support plate 10 by an application method such as follows: first, the support plate 10 is prepared, then, varnish prepared from the above-described adhesive material and solvent blended as necessary is applied on the support plate 10, and thereafter, as necessary, the solvent is distilled off.

The support sheet 9 has a thickness of, for example, 0.2 mm or more, preferably 0.5 mm or more, and 6 mm or less, preferably 2.5 mm or less.

Then, a plurality of optical semiconductor elements 3 are laminated on the support sheet 9. To be specific, the lower face of the optical semiconductor elements 3 are brought into contact with the upper face of the pressure-sensitive adhesive layer 11.

In this manner, the plurality of optical semiconductor elements 3 are disposed (placed) on the support sheet 9. That is, the plurality of optical semiconductor elements 3 are supported by the support sheet 9.

### (Encapsulation Step and First Release Step)

As shown in FIG. 2B, the encapsulation step and the first release step are the same as the encapsulation step and the release step of above-described embodiment.

With the encapsulation step and the first release step, an encapsulated optical semiconductor element 8 including the plurality of optical semiconductor elements 3, and the encapsulating sheet 1 encapsulating the plurality of optical semiconductor elements 3 all together are produced. The encapsulating sheet 1 covers the upper face and the side face of the optical semiconductor element 3. The lower face of the optical semiconductor elements 3 is exposed from the encapsulating sheet 1 and is in contact with the upper face of the pressure-sensitive adhesive layer 11.

### (Second Release Step)

After the first release step, as shown in the broken line of FIG. 2C, first, the encapsulating sheet 1 is cut in correspondence with the optical semiconductor element 3. To be specific, the encapsulation layer 6 is cut so as to surround the optical semiconductor element 3 along the thickness direction. In this manner, a plurality of encapsulated optical semiconductor elements 8 including a single optical semiconductor element 3 and an encapsulating sheet 1 encapsulating the single optical semiconductor element 3 are produced.

Then, as shown in the arrow in FIG. 2C, the encapsulated optical semiconductor element 8 is released (second release step) from the upper face of the pressure-sensitive adhesive layer 11. To be specific, when the pressure-sensitive adhesive layer 11 is an active energy ray application release sheet, active energy ray is applied to the pressure-sensitive adhesive layer 11.

In this manner, the encapsulated optical semiconductor element 8 is singularized in correspondence with the optical semiconductor element 3.

The singularized encapsulated optical semiconductor element 8 is not the optical semiconductor device 6 (ref: FIG. 2D) described later. That is, the singularized encapsulated optical semiconductor element 8 does not include the substrate 5 (ref: FIG. 2D) included in the optical semiconductor device 6. To be specific, the singularized encapsulated optical semiconductor element 8 consists of the encapsulating sheet 1, and the optical semiconductor element 3 covered with the encapsulating sheet 1. That is, the encapsulated optical semiconductor element 8 is made so as not to be electrically connected with the electrode included in the substrate 5 of the optical semiconductor device 6. Furthermore, the encapsulated optical semiconductor element 8 is a component of the optical semiconductor device 6 (ref: FIG. 2D). That is, it is a component for producing the optical semiconductor device 6, and is distributed singularly as a component, and is an industrially applicable device.

### (Mounting Step)

Thereafter, the singularized encapsulated optical semiconductor element 8 is sorted according to the emission wavelength and luminosity, and then as shown in FIG. 2D, the encapsulated optical semiconductor element 8 is mounted on the substrate 5. To be specific, the terminal (not shown) provided at the lower face of the optical semiconductor element 3 is connected with the electrode (not shown) of the substrate 5, and the encapsulated optical semiconductor element 8 is flip chip mounted on the substrate 5.

In this manner, an LED device 6 including a substrate 5, a single optical semiconductor element 3, and an encapsulating sheet 1 is produced.

This method also achieves the same operations and effects described above. That is, in the encapsulated optical semiconductor element 8 and the optical semiconductor device 6, the optical semiconductor element 3 is encapsulated with the encapsulating sheet 1 having excellent moldability, transparency, and encapsulation characteristics, and therefore have excellent reliability and luminosity.

In the above-described encapsulation step in the embodiment, plasticization by heat and thermosetting of the silicone resin composition in the encapsulating sheet 1 in B-stage are conducted by heating twice at different temperatures, that is, two-stage heating. But for example, the encapsulating sheet 1 in B-stage can also be plasticized and then cured by heating at once, that is, 1-stage heating.

### EXAMPLES

The numeral values in Synthesis Example, Preparation Examples, and Examples can be replaced with the numeral values (that is, upper limit value or lower limit value) described in the above-described embodiment.

### <Synthesis of Alkenyl Group-Containing Polysiloxane and Hydrosilyl Group-Containing Polysiloxane>

### Synthesis Example 1

A four-neck flask equipped with a stirrer, a reflux condenser tube, an inlet, and a thermometer was charged with 93.2 g of 1,3-divinyl-1,1,3,3-tetramethyldisiloxane, 140 g of water, 0.38 g of trifluoromethane sulfonic acid, and 500 g of toluene, and the mixture was stirred. While stirring the mixture, a mixture of 729.2 g of methylphenyldimethoxysilane and 330.5 g of phenyltrimethoxysilane was dropped taking 1 hour, and thereafter, the mixture was refluxed while heating for 1 hour. Thereafter, the mixture was cooled, and the bottom layer (water layer) was separated and removed, and the upper layer (toluene solution) was washed with water three times. To the toluene solution washed with water, 0.40 g of potassium hydroxide was added, and refluxed while removing water from the water separation tube. After completion of water removal, refluxing was conducted for further 5 hours, and cooling was conducted. Thereafter, 0.6 g of acetic acid was introduced for neutralization, and then, filtering was conducted. The obtained toluene solution was washed with water three times. Thereafter, the pressure was reduced for concentration, thereby producing a liquid-state alkenyl group-containing polysiloxane A. The alkenyl group-containing polysiloxane A had an average unit formula and an average composition formula shown below.

((CH₂═CH)(CH₃)₂SiO_{1/2})_{0.15}(CH₃C₆H₅SiO_{2/2})_{0.60}(C₆H₅SiO_{3/2})_{0.25} average unit formula:

(CH₂═CH)_{0.15}(CH₃)_{0.90}(C₆H₅)_{0.85}SiO_{1.05} average composition formula:

That is, the alkenyl group-containing polysiloxane A is represented by the above-described average composition formula (1) in which R¹ is a vinyl group, R² is a methyl group and a phenyl group, and a=0.15, b=1.75.

The weight-average molecular weight based on polystyrene standard measured by gel permeation chromatography of the alkenyl group-containing polysiloxane A was 2300.

### Synthesis Example 2

A four-neck flask equipped with a stirrer, a reflux condenser tube, an inlet, and a thermometer was charged with 93.2 g of 1,3-divinyl-1,1,3,3-tetramethyldisiloxane, 140 g of water, 0.38 g of trifluoromethanesulfonic acid, and 500 g of toluene, and the mixture was stirred. While stirring the mixture, a mixture of 173.4 g of diphenyldimethoxysilane and 300.6 g of phenyltrimethoxysilane was dropped taking 1 hour. After the dropping was completed, the mixture was refluxed while heating for 1 hour. Thereafter, the mixture was cooled, and the bottom layer (water layer) was separated and removed, and the upper layer (toluene solution) was washed with water three times. To the toluene solution washed with water, 0.40 g of potassium hydroxide was added, and refluxed while removing water from the water separation tube. After completion of water removal, refluxing was conducted for further 5 hours, and cooling was conducted. 0.6 g of acetic acid was introduced for neutralization, and then filtering was conducted. The obtained toluene solution was washed with water three times. Thereafter, the pressure was reduced for concentration, thereby producing a liquid-state alkenyl group-containing polysiloxane B. The alkenyl group-containing polysiloxane B had an average unit formula and an average composition formula shown below.

(CH₂═CH(CH₃)₂SiO_{1/2})_{0.31}((C₆H₅)₂SiO_{2/2})_{0.22}(C₆H₅SiO_{3/2})_{0.47} average unit formula:

(CH₂═CH)_{0.31}(CH₃)_{0.62}(C₆H₅)_{0.91}SiO_{1.08} average composition formula:

That is, the alkenyl group-containing polysiloxane B is represented by the above-described average composition formula (1) in which R¹ is a vinyl group, R² is a methyl group and a phenyl group, and a=0.31, b=1.53.

The weight-average molecular weight based on polystyrene standard measured by gel permeation chromatography of the alkenyl group-containing polysiloxane B was 1000.

### Synthesis Example 3

A four-neck flask equipped with a stirrer, a reflux condenser tube, an inlet, and a thermometer was charged with 325.9 g of diphenyldimethoxysilane, 564.9 g of phenyltrimethoxysilane, and 2.36 g of trifluoromethanesulfonic acid, and the mixture was stirred. To the mixture, 134.3 g of 1,1,3,3-tetramethyldisiloxane was added. While stirring the mixture, 432 g of acetic acid was dropped taking 30 minutes. After completion of the dropping, while stirring the mixture, the temperature was increased to 50° C., and reaction was conducted for 3 hours. After cooling was conducted to room temperature, toluene and water were added, mixed well and allowed to stand, and the bottom layer (water layer) was separated and removed. Thereafter, the upper layer (toluene solution) was washed with water three times, and then the pressure was reduced for concentration, thereby producing a hydrosilyl group-containing polysiloxane C (cross-linking agent C).

The hydrosilyl group-containing polysiloxane C had an average unit formula and an average composition formula shown below.

(H(CH₃)₂SiO_{1/2})_{0.33}((C₆H₅)₂SiO_{2/2})_{0.22}(C₆H₅PhSiO_{3/2})_{0.45} average unit formula:

H_{0.33}(CH₃)_{0.66}(C₆H₅)_{0.89}SiO_{1.06} average composition formula:

That is, the hydrosilyl group-containing polysiloxane C is represented by the above-described average composition formula (2) in which R³ is a methyl group and a phenyl group, and c=0.33, d=1.55.

The weight-average molecular weight based on polystyrene standard measured by gel permeation chromatography of the hydrosilyl group-containing polysiloxane C was 1000.

### Synthesis Example 4

A four-neck flask equipped with a stirrer, a reflux condenser tube, an inlet, and a thermometer was charged with 100 g of toluene, 50 g of water, and 50 g of isopropyl alcohol, and the mixture was stirred. While stirring the mixture, a mixture of 16.7 g of vinyltrichlorosilane, 87.1 g of methyltrichlorosilane, and 66.4 g of phenyltrichlorosilane was dropped taking 1 hour. After the dropping was completed, the mixture was stirred for 1 hour under normal temperature. The bottom layer (water layer) was separated and removed, and the upper layer (toluene solution) was washed with water three times. To the toluene solution washed with water, 0.12 g of potassium hydroxide was added, and refluxed while removing water from the water separation tube. After completion of water removal, refluxing was conducted for further 5 hours, and cooling was conducted. Thereafter, the pressure was reduced for concentration, thereby producing a liquid-state alkenyl group-containing polysiloxane D.

The alkenyl group-containing polysiloxane D had an average unit formula and an average composition formula shown below.

(CH₂═CHSiO_{3/2})_{0.10}(CH₃SiO_{3/2})_{0.58}(C₆H₅SiO_{3/2})_{0.31} average unit formula:

(CH₂═CH)_{0.10}(CH₃)_{0.58}(C₆H₅)_{0.31}SiO_{1.50} average composition formula:

That is, the alkenyl group-containing polysiloxane D is represented by the average composition formula (1) in which R¹ is a vinyl group, R² is a methyl group and a phenyl group, and a=0.10, b=0.89.

The weight-average molecular weight based on polystyrene standard measured by gel permeation chromatography of the alkenyl group-containing polysiloxane D was 3400.

### <Other Materials>

Materials other than alkenyl group-containing polysiloxane and hydrosilyl group-containing polysiloxane are shown below.

### LR7665:

Trade name, methyl-based silicone resin composition, manufactured by wacker asahikasei silicone co., ltd.

### Inorganic Filler A:

Inorganic filler having a refraction of 1.55, composition and composition ratio (mass %): SiO₂/Al₂O₃/CaO/MgO=60/20/15/5, average particle size: 3 μm, 15 μm, 30 μm, 80 μm (classified into the average particle sizes, and the average particle size was adjusted.)

### Inorganic Filler B:

Inorganic filler having a refraction of 1.57, composition and composition ratio (mass %): SiO₂/Al₂O₃/CaO/SrO=57.3/15.0/21.2/6.5, average particle size: 15 μm.

### Inorganic Filler C:

Inorganic filler having a refraction of 1.52, composition and composition ratio (mass %):SiO₂/ZrO₂/Al₂O₃/CaO/BaO/Sb₂O₃=51.1/2.9/15.1/9.9/20.5/0.5, average particle size: 15 μm.

### FB-40S:

Trade name, manufactured by DENKI KAGAKU KOGYO KABUSHIKI KAISHA, refraction 1.46, silica, average particle size: 40 μm
Platinum carbonyl complex:
Trade name “SIP6829.2”, manufactured by Gelest, Inc., platinum concentration 2.0 mass %

### <Preparation of Silicone Resin Composition>

### Preparation Example 1

A silicone resin composition A was prepared by mixing 20 g of alkenyl group-containing polysiloxane A (Synthesis Example 1), 25 g of alkenyl group-containing polysiloxane B (Synthesis Example 2), 25 g of hydrosilyl group-containing polysiloxane C (Synthesis Example 3, cross-linking agent C), and 5 mg of platinum carbonyl complex.

### Preparation Example 2

A silicone resin composition B was prepared by mixing 70 g of alkenyl group-containing polysiloxane D (Preparation Example 4), 30 g of hydrosilyl group-containing polysiloxane C (Preparation Example 3, cross-linking agent C), and 5 mg of platinum carbonyl complex.

### Comparative Preparation Example 1

A silicone resin composition C was prepared by mixing silicone resin composition A of Preparation Example 1 and LR7665 so that the mass ratio was 1:1.

### <Production of Encapsulating Sheet>

### Example 1

The silicone resin composition A was mixed with the inorganic filler A so that the inorganic filler A was 50 mass % relative to the total of the silicone resin composition A and the inorganic filler A, thereby preparing varnish of an encapsulating composition. That is, in the encapsulating composition, the silicone resin composition A mixing ratio was 50 mass % and the inorganic filler A mixing ratio was 50 mass %.

Then, the prepared varnish was applied on the surface of the release sheet (PTE sheet, trade name “SS4C”, manufactured by Nippa CO., LTD.) having a thickness of 600 μm with an applicator so that the thickness after heating was 600 μm, and thereafter, heating at 90° C. was conducted for 9.5 minutes, thereby bringing the silicone resin composition in the varnish into B-stage (semi-cured). An encapsulating sheet was produced in this manner.

### Examples 2 to 7 and Comparative Examples 1 to 5

An encapsulating sheet was produced in the same manner as in Example 1, except that preparation of varnish was conducted and heating conditions were changed according to Table 1 below.

In Comparative Example 3, homogenous varnish could not be prepared, and therefore, the varnish could not be applied to the release sheet.

### Evaluation

The following evaluations were conducted. The results are shown in Table 1.

### (1) Measurement of Phenyl Group Content in Hydrocarbon Group (R⁵) of Product Obtained by Reaction of Silicone Resin Composition

The phenyl group content (mol %) of the hydrocarbon group (R⁵ in average composition formula (3)) directly connected to the silicon atom in the product obtained by reaction of only silicone resin compositions A to C (that is, silicone resin composition in which no inorganic filler contained) was calculated by ¹H-NMR and ²⁹Si-NMR.

To be specific, A-stage silicone resin compositions A to C were reacted without adding the inorganic filler at 100° C. for 1 hour (completely cured, brought into C-stage), thereby producing a product.

Then, the product was subjected to ¹H-NMR and ²⁹Si-NMR measurement, thereby calculating the percentage (mol %) of the phenyl group in the hydrocarbon group (R⁵) directly connected to the silicon atom.

### (2) Presence or Absence of Inorganic Filler Sedimentation in Varnish

Presence or absence of the inorganic filler sedimentation in A-stage varnish was observed visually after allowing the varnish to stand for 24 hours after preparation.

### (3) Shear Storage Modulus G′ of Encapsulating Sheet at 80° C.

A sample was taken from the B-stage encapsulating sheet, and subjected to dynamic viscoelasticity measurement (DMA). Conditions of the dynamic viscoelasticity measurement are shown below. Then, the shear storage modulus G′ of the sample at 80° C. was calculated.
DMA device: rotational rheometer (C-VOR device, manufactured by Malvern Instruments Ltd)
Sample amount: 0.1 g

### Distortion: 1%

### Frequency: 1 Hz

Plate diameter: 25 mm
Gap between plates: 450 μm
Temperature increase rate: 20° C./min
Temperature range: 20 to 150° C.

### (4) Thickness Uniformity of Encapsulating Sheet

Thickness uniformity of the B-stage encapsulating sheet was evaluated based on the criteria below.
GOOD: absolute value of difference between target thickness (600 μm) and actual thickness was less than 10%.
AVERAGE: absolute value of difference between target thickness and actual thickness was 10% or more and less than 20%.
BAD: absolute value of difference between target thickness and actual thickness was 20% or more.

### (5) Transmittance of Encapsulating Sheet for Light Having a Wavelength of 460 nm

Transmittance of light having a wavelength of 460 nm of the B-stage encapsulating sheet having a thickness of 600 μm was measured using an integrating sphere (Halfmoon, manufactured by Otsuka Electronics Co. Ltd.).

### (6) Cutting Processability

Cutting processability of the B-stage encapsulating sheet was evaluated based on the criteria below.
GOOD: high shape retainability (self-support of the sheet), end portion (unnecessary portion) could be cut.
BAD: low shape retainability, end portion could not be cut.

### (7) Encapsulation Characteristics (Presence or Absence of Wire Deformation)

The optical semiconductor element connected to the electrode of the substrate by wire bonding was encapsulated with the B-stage encapsulating sheet.

To be specific, the B-stage encapsulating sheet laminated on the release sheet and the substrate and the optical semiconductor element mounted on the substrate were prepared (ref: FIG. 1A, preparation step). Then, the optical semiconductor element was encapsulated with the encapsulating sheet (ref: FIG. 1B, encapsulation step). To be specific, the substrate on which the optical semiconductor element is mounted is placed on a hot plate of 60° C., and then the encapsulating sheet is placed on the substrate and the optical semiconductor element, the encapsulating sheet is softened, and then the encapsulating sheet was completely cured (brought into C-stage). Thereafter, the substrate was taken out from the hot plate and allowed to stand to cool, and then the release sheet was released from the encapsulating sheet (ref: FIG. 1C, release step).

Then, in the encapsulation step, deformation of the wire was observed, thereby evaluating encapsulation characteristics of the encapsulating sheet based on the criteria below.

GOOD: No deformation was observed on the wire. The optical semiconductor element was lighted in the optical semiconductor device.
AVERAGE: Slight deformation was observed in the wire. The optical semiconductor element was lighted in the optical semiconductor device.
BAD: Massive deformation was observed in the wire. The optical semiconductor element was not lighted in the optical semiconductor device.

TABLE 1

| | | | | | | | | Evaluation |
|---|---|---|---|---|---|---|---|---|
| | | | | | | | | Phenyl group |
| | Encapsulating composition (Varnish) | | | | | | | content in R5 of |
| | | | Inorganic filler | | | | | average |
| | Silicone resin composition | | | | | Blending | | composition |
| | | Blending | | | | ratio | | formula (3) of |
| | | ratio | | Average | | (relative | | product obtained |
| | | (relative to | | particle | | to | | by reaction of |
| | | Varnish) | | size | | Varnish) | Heating | silicone resin |
| | Type | [mass %] | Type | [μm] | Refraction | [mass %] | conditions | composition [%] |
| Ex. 1 | Silicone resin | 50 | Inorganic | 15 | 1.55 | 50 | 90° C., | 48 |
| | composition A | | filler A | | | | 9.5 min | |
| Ex. 2 | Silicone resin | 50 | Inorganic | 30 | 1.55 | 50 | 90° C., | 48 |
| | composition A | | filler A | | | | 9.5 min | |
| Ex. 3 | Silicone resin | 50 | Inorganic | 15 | 1.57 | 50 | 90° C., | 48 |
| | composition A | | filler B | | | | 9.5 min | |
| Ex. 4 | Silicone resin | 50 | Inorganic | 15 | 1.55 | 50 | 100° C., | 38 |
| | composition B | | filler A | | | | 15 min | |
| Ex. 5 | Silicone resin | 50 | Inorganic | 15 | 1.52 | 50 | 100° C., | 38 |
| | composition B | | filler C | | | | 15 min | |
| Ex. 6 | Silicone resin | 30 | Inorganic | 15 | 1.55 | 70 | 90° C., | 48 |
| | composition A | | filler A | | | | 9.5 min | |
| Ex. 7 | Silicone resin | 30 | Inorganic | 15 | 1.55 | 70 | 90° C., | 48 |
| | composition A | | filler A | | | | 85 min | |
| Comp. | Silicone resin | 100 | Not added | | | | 90° C., | 48 |
| Ex. 1 | composition A | | | | | | 8.5 min | |
| Comp. | Silicone resin | 50 | FB-40S | 40 | 1.46 | 50 | 90° C., | 48 |
| Ex. 2 | composition A | | | | | | 8.5 min | |
| Comp. | Silicone resin | 30 | Inorganic | 3 | 1.55 | 70 | — | 48 |
| Ex. 3 | composition A | | filler A | | | | | |
| Comp. | Silicone resin | 50 | Inorganic | 80 | 1.55 | 50 | — | 48 |
| Ex. 4 | composition A | | filler A | | | | | |
| Comp. | Silicone resin | 50 | Inorganic | 15 | 1.55 | 50 | 100° C., | 19 |
| Ex. 5 | composition | | filler A | | | | 15 min | |
| | C 1 | | | | | | | |

| | Evaluation | | | | | |
|---|---|---|---|---|---|---|
| | | | | | | Encapsulation |
| | Presence or | | | Transmittance | | characteristic |
| | absence of | | | for light | | (Presence or |
| | inorganic filler | Shear storage | | having a | | absence of |
| | sedimentation | modulus G′ | | wavelength | Cutting | wire |
| | in Varnish | at 80° C. [Pa] | Thickness | of 460 nm [%] | Processability | deformation) |
| Ex. 1 | Absent | 120 | AVERAGE | 100 | GOOD | AVERAGE |
| Ex. 2 | Absent | 120 | AVERAGE | 100 | GOOD | AVERAGE |
| Ex. 3 | Absent | 120 | AVERAGE | 95 | GOOD | AVERAGE |
| Ex. 4 | Absent | 120 | AVERAGE | 97 | GOOD | AVERAGE |
| Ex. 5 | Absent | 120 | AVERAGE | 97 | GOOD | AVERAGE |
| Ex. 6 | Absent | 120 | GOOD | 99 | GOOD | AVERAGE |
| Ex. 7 | Absent | 25 | GOOD | 99 | GOOD | GOOD |
| Comp. | Absent | 25 | BAD | 100 | BAD | GOOD |
| Ex. 1 | | | | | | |
| Comp. | Absent | 25 | AVERAGE | 63 | GOOD | GOOD |
| Ex. 2 | | | | | | |
| Comp. | Absent | Could not be applied because varnish was lumpy | | | | |
| Ex. 3 | | | | | | |
| Comp. | Present | Inorganic filler sedimentation caused, and therefore Evaluation afterwards | | | | |
| Ex. 4 | | was not conducted | | | | |
| Comp. | Absent | 2500 | GOOD | 20 | GOOD | BAD |
| Ex. 5 | | | | | | |

1 Silicone resin composition C = Silicone resin composition + LR7665(1:1)

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICABILITY

The encapsulating sheet is used so as to encapsulate the optical semiconductor element.

### DESCRIPTION OF REFERENCE NUMERALS

1 encapsulating sheet
3 optical semiconductor element
5 substrate
6 optical semiconductor device
8 encapsulated optical semiconductor element

1-9. (canceled)

10. An encapsulating sheet used to encapsulate an optical semiconductor element, the encapsulating sheet formed into a sheet in B-stage from an encapsulating composition comprising:
a silicone resin composition containing
an alkenyl group-containing polysiloxane having two or more alkenyl groups and/or cycloalkenyl groups in its molecule,
a hydrosilyl group-containing polysiloxane having two or more hydrosilyl groups in its molecule, and
a hydrosilylation catalyst, and
an inorganic filler having a refraction of 1.50 or more and 1.60 or less, and an average particle size of 10 μm or more and 50 μm or less,
wherein the alkenyl group-containing polysiloxane is represented by the average composition formula (1) below,
R¹ₐR²_{b}SiO_{(4-a-b)/2} average composition formula (1):
(where R¹ represents an alkenyl group having 2 to 10 carbon atoms and/or a cycloalkenyl group having 3 to 10 carbon atoms. R² represents an unsubstituted or substituted monovalent hydrocarbon group having 1 to 10 carbon atoms (excluding alkenyl group and cycloalkenyl group). a is 0.05 or more and 0.50 or less, b is 0.80 or more and 1.80 or less.)
the hydrosilyl group-containing polysiloxane is represented by the average composition formula (2) below,
H_{c}R³_{d}SiO_{(4-c-d)/2} average composition formula (2):
(where R³ represents an unsubstituted or substituted monovalent hydrocarbon group having 1 to 10 carbon atoms (excluding alkenyl group and cycloalkenyl group). c is 0.30 or more and 1.0 or less, d is 0.90 or more and 2.0 or less),
in the average composition formula (1) and the average composition formula (2), at least one of R² and R³ includes a phenyl group,
a product in C-stage produced by reaction of the silicone resin composition has a phenyl group content in a hydrocarbon group directly connected to the silicon atom calculated with ²⁹Si-NMR of 30 mol % or more and 55 mol % or less.

11. The encapsulating sheet according to claim 10, wherein the mixing ratio of the inorganic filler is 30 mass % or more and 80 mass % or less relative to the encapsulating composition.

12. The encapsulating sheet according to claim 10, wherein the encapsulating sheet in B-stage has thermoplastic and thermosetting properties together.

13. The encapsulating sheet according to claim 10, wherein the shear storage modulus G′ at 80° C. obtained by dynamic viscoelasticity measurement under conditions of a frequency of 1 Hz, a temperature increase rate of 20° C./min, and a temperature range of 20 to 150° C. is 3 Pa or more and 140 Pa or less.

14. The encapsulating sheet according to claim 10, wherein the transmittance of light having a wavelength of 460 nm is 70% or more when the thickness is 600 μm.

15. A method for producing the encapsulating sheet according to claim 10, the method comprising:
forming a coating by applying the encapsulating composition, and
heating the coating at 70° C. or more and 120° C. or less and for 8 minutes or more and 15 minutes or less.

16. An optical semiconductor device comprising:
a substrate,
an optical semiconductor element mounted on the substrate, and
the encapsulating sheet according to claim 10 encapsulating the optical semiconductor element.

17. An encapsulated optical semiconductor element comprising an optical semiconductor element, and
the encapsulating sheet according to claim 10 encapsulating the optical semiconductor element.
